(19) United States
(12) Patent Application Publication
(10) Pub. No.: US 2024/0203763 A1
(43) Pub. Date: Jun. 20, 2024

(54) USE OF SIGNAL FILTERING SCHEMES IN HIGH TCR BASED CONTROL

(71) Applicant: LAM RESEARCH CORPORATION, Fremont, CA (US)

(72) Inventors: Ramesh CHANDRASEKHARAN, Lake Oswego, OR (US); Mohan THILAGARAJ, Tualatin, OR (US); Karl Frederick LEESER, West Linn, OR (US)

(21) Appl. No.: 18/288,144

(22) PCT Filed: Apr. 25, 2022
(86) PCT No.: PCT/US2022/026124

§ 371 Date: Oct. 24, 2023

Related U.S. Application Data
(60) Provisional application No. 63/180,883, filed on Apr. 28, 2021.

(51) Int. Cl. H01L 21/67; C23C 16/458; C23C 16/46

(52) U.S. Cl. CPC H01L 21/67103; C23C 16/4586; C23C 16/46; H01L 21/67248

(57) ABSTRACT

A controller to control a temperature of a first substrate support in a substrate processing system includes a resistance calculation module to calculate a first resistance of a first heater element of a plurality of heater elements of the first substrate support, a temperature calculation module to calculate a first temperature of the first heater element based on the calculated first resistance, and a filter module to filter a first signal that corresponds to the calculated first resistance. The temperature calculation module selectively causes the filter module to filter the first signal in response to a determination of whether at least one condition associated with operation of the substrate processing system is met.

### CROSS-REFERENCE TO RELATED APPLICATIONS

This application claims the benefit of U.S. Provisional Application No. 63/180,883, filed on Apr. 28, 2021. The entire disclosure of the application referenced above is incorporated herein by reference.

### FIELD

The present disclosure relates to temperature control during substrate processing.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, photoresist removal, etc. During processing, the substrate is arranged on a substrate support such as an electrostatic chuck. One or more process gases may be introduced into the processing chamber. The one or more processing gases may be delivered by a gas delivery system to the processing chamber. In some systems, the gas delivery system includes a manifold connected by one or more conduits to a showerhead that is located in the processing chamber.

### SUMMARY

A controller to control a temperature of a first substrate support in a substrate processing system includes a resistance calculation module to calculate a first resistance of a first heater element of a plurality of heater elements of the first substrate support, a temperature calculation module to calculate a first temperature of the first heater element based on the calculated first resistance, and a filter module to filter a first signal that corresponds to the calculated first resistance. The temperature calculation module selectively causes the filter module to filter the first signal in response to a determination of whether at least one condition associated with operation of the substrate processing system is met.

In other features, the at least one condition corresponds to an operation of the substrate processing system that is associated with a temperature change in the first heater element. The temperature calculation module determines, based on the calculated first resistance, whether a temperature change in the first heater element is expected and selectively causes the filter module to filter the first signal in response to a determination that the temperature change is not expected. The temperature calculation module determines, based on the calculated first resistance, whether a rate of temperature change in the first heater element exceeds a threshold and selectively causes the filter module to filter the first signal in response to a determination that the rate of temperature change exceeds the threshold.

In other features, the temperature calculation module compares a first temperature change in the first heater element with a second temperature change in a second heater element and selectively causes the filter module to filter the first signal based on the comparison. The second heater element is located in a second substrate support. The filter module applies a resistance offset to the first signal in response to the determination of whether at least one condition associated with operation of the substrate processing system is met. The controller further includes a temperature control module configured to control power provided to the first heater element based on the first signal.

In other features, the resistance calculation module receives a first current corresponding to the first heater element, receives a first voltage corresponding to the first heater element, and calculates the first resistance based on the first voltage and the first current. The temperature calculation module calculates the first temperature based on the calculated first resistance and a temperature coefficient of resistance of the first heater element.

A system includes a resistance calculation module to receive a current corresponding to a heater element in a substrate support, receive a voltage corresponding to the heater element, and calculate a resistance of the heater element based on the voltage and the current, a temperature calculation module to calculate a temperature of the heater element based on the calculated resistance, and a filter module to filter a signal that corresponds to the calculated resistance. The temperature calculation module selectively causes the filter module to filter the signal in response to a determination of whether at least one condition associated with a change in the temperature of the heater element is met. The system further includes a temperature control module configured to control power provided to the heater element based on the signal as filtered by the filter module.

In other features, the temperature calculation module determines, based on the calculated first resistance, whether at least one of the change in the temperature of the heater element is expected and a rate of the change in the temperature of the heater element exceeds a threshold. The temperature calculation module selectively causes the filter module to filter the signal in response to a determination that the change in the temperature of the heater element is not expected, a rate of the change in the temperature of the heater element exceeds a threshold, and the change in the temperature of the heater element is not within a range of a change in a temperature of another heater element.

A method of controlling a temperature of a first substrate support in a substrate processing system includes calculating a first resistance of a first heater element of a plurality of heater elements of the first substrate support, calculating a first temperature of the first heater element based on the calculated first resistance, and selectively filtering a first signal that corresponds to the calculated first resistance in response to a determination of whether at least one condition associated with operation of the substrate processing system is met.

In other features, the at least one condition corresponds to an operation of the substrate processing system that is associated with a temperature change in the first heater element. The method further includes determining, based on the calculated first resistance, whether a temperature change in the first heater element is expected and selectively filtering the first signal in response to a determination that the temperature change is not expected. The method further includes determining, based on the calculated first resistance, whether a rate of temperature change in the first heater element exceeds a threshold and selectively filtering the first signal in response to a determination that the rate of temperature change exceeds the threshold.

In other features, the method further includes comparing a first temperature change in the first heater element with a second temperature change in a second heater element and selectively filtering the first signal based on the comparison. The second heater element is located in a second substrate support. The method further includes controlling power provided to the first heater element based on the first signal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system according to the present disclosure;

FIG. 2A is an example substrate support according to the present disclosure;

FIG. 2B is a plan view of an example substrate support according to the present disclosure;

FIG. 3 is a functional block diagram of an example controller according to the present disclosure; and

FIG. 4 illustrates steps of an example method for selectively filtering signals corresponding to calculated resistances in a substrate support according to the present disclosure.

In the drawings, reference numbers may be reused to identify similar and/or identical elements.

### DETAILED DESCRIPTION

Film deposition and etching processes may vary over a spatial (i.e., x-y coordinates of a horizontal plane) distribution. For example, in deposition processes, properties of a deposited film vary across the spatial distribution. Conversely, in etching processes, etch amounts may vary across the spatial distribution.

Properties of etched and deposited films (e.g., deposited atomic layer deposition (ALD) films, plasma enhanced chemical vapor deposition (PECVD) films, etc.) may be influenced by a temperature of the substrate during deposition. Accordingly, a substrate support (e.g., a pedestal including a planar upper surface configured to support a substrate) may implement a temperature control system. For example, during an ALD process (e.g., deposition of an oxide film), a substrate is arranged on the pedestal. Typically, an ALD pedestal comprises a single temperature-controlled zone. In some examples, an ALD pedestal may include multiple temperature-controlled zones (e.g., a center, inner zone and an outer zone). A heater layer may be embedded within an upper layer of the ALD pedestal. The heater layer may be configured to receive a voltage/current to function as a resistive heather to heat the pedestal and the substrate arranged thereon. The heater layer may be configured to heat a single zone or to separately heat multiple zones of the pedestal, such as an inner zone and an outer zone.

Typically, a pedestal including a single zone or multiple zones may include only a single temperature sensor arranged in a central region of the pedestal due to manufacturing and architecture constraints. In other examples, a pedestal may not include any temperature sensors. Accordingly, accurate control of the temperature of the pedestal may be limited.

In some examples, the temperature control system may be configured to calculate temperatures of heater elements and respective zones of the pedestal based on a temperature coefficient of resistance (TCR), voltage, and current of each heater element. For example, the pedestal may include a heater layer including heater elements having a high TCR (e.g., greater than or equal to 1.0%). For example, the heater elements may include, but are not limited to, molybdenum and nickel heater elements. The TCR may be positive or negative. A positive TCR is associated with an increased resistance as temperature increases. Conversely, a negative TCR is associated with a decreased resistance as temperature increases.

Accordingly, an overall resistance of the heater layer (i.e., of one or more heater elements of a corresponding heater layer) is indicative of the temperature of the heater layer. A current provided to the heater layer and a voltage across the heater layer may be measured to calculate the resistance of the heater layer. Respective temperatures of the outer zone and the inner zone may be calculated based on changes in the resistance of the heater layer. In this manner, temperatures of different zones of the substrate support (and, therefore, of regions of the substrate in the different zones) may be controlled independently of one another and independently of thermal load and other system transients.

Measurement signals indicative of the current and voltage are used to calculate the resistance. System noise and spurious changes in resistance can cause inaccurate resistance and temperature calculations and flawed temperature control. For example, system variations unrelated to temperature changes (e.g., component wear or other structural variations) may cause permanent or intermittent changes in resistance. Accordingly, any resistance changes that are not caused by actual temperature changes may cause inaccurate temperature control.

The temperature control system may include one or more filters (e.g., first order, linear filters). For example, the filters may be configured to filter noise from the measurement signals. However, the filters do not filter resistance changes that may be caused by variations such as by oxidation, component wear, loosening of fittings, connections, and splices, etc.

Temperature control systems and methods according to the present disclosure implement a filter system configured to differentiate between noise and resistance changes caused by structural variations. For example, the filter system implements both linear and non-linear filters. The filter system selectively filters the measurement signals to remove both noise and resistance changes caused by system variations unrelated to temperature changes while preserving signal characteristics related to actual temperature changes.

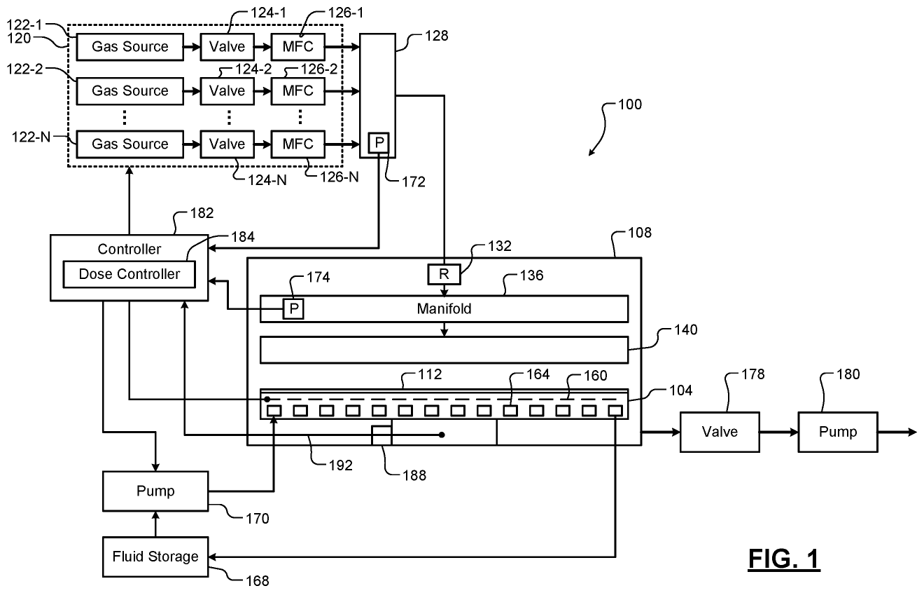

Referring now to FIG. 1, an example of a substrate processing system 100 including a substrate support (e.g., a pedestal, such as an ALD or PECVD pedestal) 104 according to the present disclosure is shown. The substrate support 104 is arranged within a processing chamber 108. A substrate 112 is arranged on the substrate support 104 during processing.

A gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a manifold 136. An output of the manifold 136 is input to a multi-injector showerhead 140. While the manifold 128 and 136 are shown, a single manifold can be used.

The substrate support 104 includes a plurality of zones. As shown, the substrate support 104 includes an inner (central) zone 144 and an outer zone 148. A temperature of the substrate support 104 may be controlled by using one or more heater elements (e.g., resistive heaters) 160 arranged in the substrate support 104 as described below in more detail. In other examples, the substrate support 204 may include more (e.g., three or more) zones or only one zone.

In some examples, the substrate support 104 may include coolant channels 164. Cooling fluid is supplied to the coolant channels 164 from a fluid storage 168 and a pump 170. Pressure sensors 172, 174 may be arranged in the manifold 128 or the manifold 136, respectively, to measure pressure. A valve 178 and a pump 180 may be used to evacuate reactants from the processing chamber 108 and/or to control pressure within the processing chamber 108.

A controller 182 may include a dose controller 184 that controls dosing provided by the multi-injector showerhead 140. The controller 182 also controls gas delivery from the gas delivery system 120. The controller 182 controls pressure in the processing chamber and/or evacuation of reactants using the valve 178 and the pump 180. The controller 182 controls the temperature of the substrate support 104 and the substrate 112 based upon temperature feedback (e.g., from sensors (not shown) in the substrate support and/or sensors (not shown) measuring coolant temperature).

One or more signals provided to and from the substrate support 104 (e.g., between the substrate support 104 and the controller 182) are routed through a filter box 188. For example, measurement signals 192 may indicate respective voltages and currents of the heater elements 160. The controller 182 is configured to calculate temperatures of the heater elements 160 and respective zones of the substrate support 104 based on TCR, voltage, and current of each of the heater elements 160 based in part on the measurement signals 192. The controller 182 according to the present disclosure is further configured to selectively filter a resistance value calculated using the measurement signals 192 as described below in more detail.

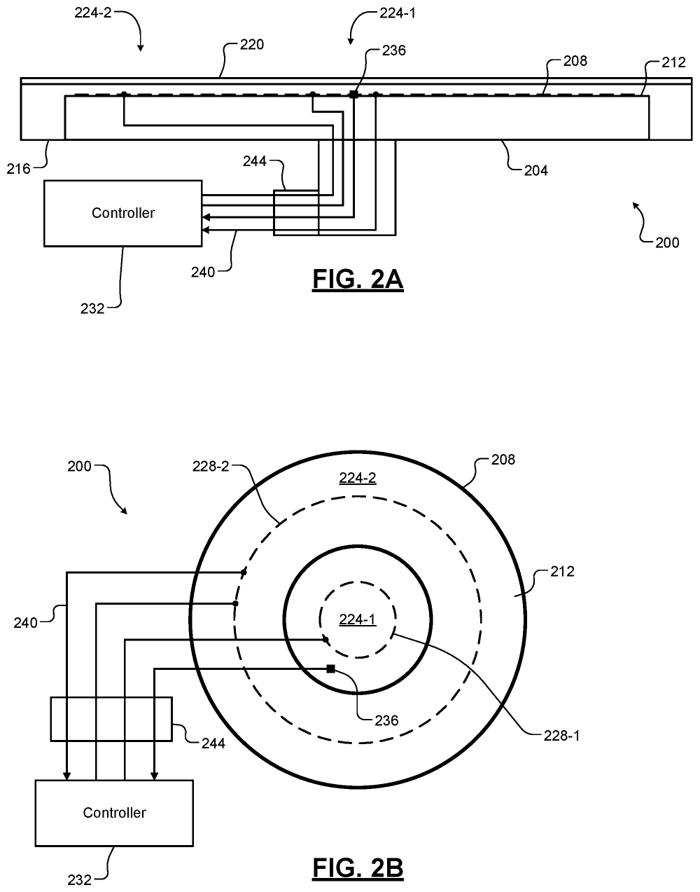

Referring now to FIGS. 2A and 2B, a simplified example substrate support 200 according to the present disclosure is shown schematically and in a plan view, respectively. The substrate support 200 includes a conductive baseplate 204 and a heater layer 208. For example, the heater layer 208 may be formed on an upper surface 212 of the baseplate 204. The baseplate 204 is arranged within an upper plate (e.g., an aluminum diffuser plate) 216. Accordingly, the heater layer 208 is embedded within the substrate support 200. A substrate 220 may be arranged on the substrate support 200 for processing (e.g., for ALD or PECVD processing).

As shown, the substrate support 200 (and, accordingly, the heater layer 208) includes two zones: an inner, central zone 224-1 and an outer zone 224-2, referred to collectively as zones 224. The inner zone 224-1 and the outer zone 224-2 include respective resistive heater elements 228-1 and 228-2, referred to collectively as heater elements 228. For example only, the heater elements 228 are comprised of a material having a positive or negative TCR greater than 1.0%, such as molybdenum, nickel, tungsten, etc. The heater elements 228-1 and 228-2 may be separately controllable. For example, the heater elements 228 may receive power (e.g., current) in response to commands from a controller 232, which may correspond to the controller 182 of FIG. 1. In other examples, the substrate support 200 may correspond to only a single controllable zone and heater element. In some examples, the substrate support 200 may include a centrally-located (i.e., in the inner zone 224-1) temperature sensor 236. The controller 232 is configured to calculate resistances of the heater elements 228-1 and 228-2 based on measured current and voltages associated with the heater elements 228-1 and 228-2 and calculate and control respective temperatures in the zones 224-1 and 224-2 based on the calculated resistances as described below in more detail.

Measurement signals 240 indicative of the current and voltages of the heater elements 228 are provided to the controller 232. For example, the measurement signals 240 may include raw voltage and current measurements. The controller 232 calculates the resistances (i.e., resistance values) of the heater elements 228 using the voltage and current measurements. A filter box 244 may filter noise from measurement signals 240. For example, the filter box 244 may implement a linear filter configured to filter system noise (e.g., periodic or high frequency noise) from the measurement signals 240. The controller 232 according to the present disclosure includes a filter module configured to selectively filter the calculated resistance values.

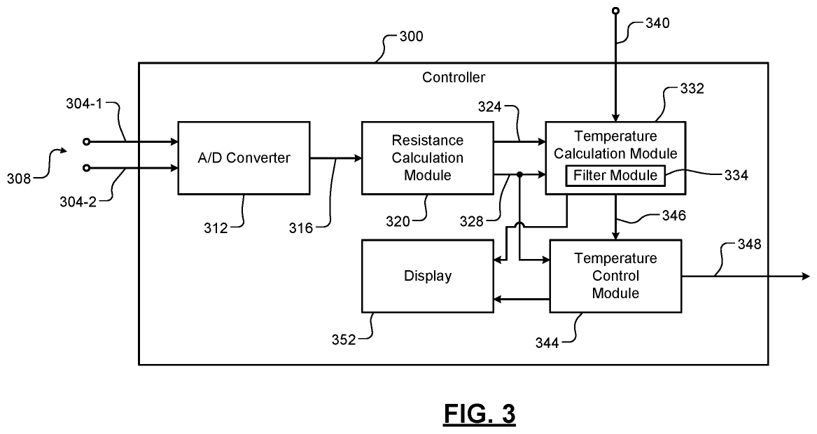

Referring now to FIG. 3, an example controller 300 configured to calculate and control temperatures in the zones 224-1 and 224-2 is shown. The controller 300 receives signals including, but not limited to, voltage signals 304-1 and current signals 304-2, referred to collectively as signals 304). The voltage signals 304-1 may include signals indicating respective voltages of the heater elements 228 of the zones 224. The current signals 304-2 may include signals indicating respective currents through the heater elements 228. For example, the voltage signals 304-1 and the current signals 304-2 may correspond to analog measurement signals provided from respective sensors 308 via the filter box 244 (not shown in FIG. 3).

An analog-to-digital (A/D) converter 312 converts the voltage signals 304-1 and the current signals 304-2 to digital signals 316. Although shown as a single A/D converter 312, the controller 300 may implement a different A/D converter for each of the signals 304. A resistance calculation module 320 is configured to calculate a resistance value of each of the heater elements 228 based on the digital signals 316. For example, the resistance calculation module 320 may calculate the resistances based on the indicated voltages and currents in accordance with Ohm's law and output signals 324 indicating the calculated resistances. In some examples, the resistance calculation module 320 may correct for gain and/or apply an offset to the digital signals 316 prior to calculating the resistances. In some examples, the resistance calculation module 320 may calculate a power output of each of the heater elements 228 based on the indicated voltages and currents (e.g., by multiplying voltage and current for each of the heater elements 228) and output signals 328 indicating the calculated power values.

A temperature calculation module 332 according to the present disclosure receives the calculated resistances for each of the heater elements 228 and calculates a temperature in the respective zones 224-1 and 224-2 based on the calculated resistances. For example, as described above, the material of the heater elements 228 has a known TCR, which is indicative of resistance changes in response to temperature changes. Accordingly, for a given heater element 228 and material, the temperature calculation module 332 is configured to calculate changes in temperature of the corresponding zone 224 based on changes in resistance.

For example, a temperature of a zone 224 may be correlated to a resistance of the heater element 228 according to a curve/slope defined by T=TCR*R−Tc (Equation 1), where T is the temperature of the zone 224, R is the calculated resistance of the heater element 228, TCR is a TCR modifier (e.g., ° C./Ohm), and Tc is a temperature constant offset (e.g., 230° C.). For example, for molybdenum, the temperature of a heater element may be calculated according to T=(46° C./Ohm)*R−230° C. The temperature calculation module 332 stores data indicating the correlation between the temperatures of the zones 224 and the resistances of the heater elements 228. In one example, the temperature calculation module 232 stores a resistance to temperature (R/T) conversion table that indexes a range of possible measured resistances of the heater elements 228 to corresponding temperatures (e.g., in 1° C. intervals) of the zones 224 in accordance with the curve defined by Equation 1. In other examples, the temperature calculation module 332 may store and execute a model, a formula, etc. to calculate the temperatures of the zones 224 based on the calculated resistances. The temperature calculation module 332 outputs respective temperatures of the zones 224-1 and 224-2 based on the calculated resistances and the R/T conversion table.

The temperature calculation module 332 may generate the R/T conversion table during an initial calibration (e.g., during manufacture, assembly, servicing, etc. of the processing chamber 108, during installation and/or servicing of the substrate support 200, etc.). For example, during calibration, resistances of the heater elements 228 may be calculated while measuring temperatures in the zones 224 with one or more temporary temperature sensors (e.g., sensors of a temperature sensing test substrate arranged on the substrate support 200).

The temperature calculation module 332 according to the present disclosure includes a filter module 334 configured to selectively filter the calculated resistance values and/or the calculated temperatures. In other words, the filter module 334 as described below may selectively filter the calculated resistance values prior to being converted to the calculated temperatures or may filter the calculated temperatures subsequent to being converted from the calculated resistance values. For example purposes, the filter module 334 will be described as operating in accordance with the calculated resistance values prior to being converted to the calculated temperatures.

The temperature calculation module 332 is configured to selectively apply the filter module 334 to the calculated resistance values (i.e., the signals 324) in response to one or more conditions being met. In other words, if the one or more conditions are not met, the temperature calculation module 332 converts the calculated resistance values indicated by the signals 324 to temperatures as described above. Conversely, if the one or more conditions are met, the filter module 334 filters the signals prior to conversion to the calculated temperatures.

For example, the temperature calculation module 332 may receive one or more signals 340 indicative of respective conditions in the substrate processing system 100 that may affect resistance and temperature measurements. For example, the signals 340 may indicate various operating parameters of the substrate processing system 100, such as indication of whether a substrate is present on the substrate support 200, which process steps are being performed, process parameters (e.g., process or purge gas flow, pressure changes, plasma activation, changes in RF power, etc.), movement of components of the substrate support 200, etc. The temperature calculation module 332 may compare the information indicated by the signals 340 to stored data (e.g., a ruleset) to determine whether the one or more conditions are met.

The filter module 334 may implement linear and/or nonlinear filtering and be configured to selectively apply offsets (i.e., resistance value offsets) to the signals 324, median filtering, Kalman filtering, etc. More specifically, the filter module 334 is configured to selectively filter the signals 324 based upon a determination of whether a change in the resistance values indicated by the signals 324 meets the one or more conditions.

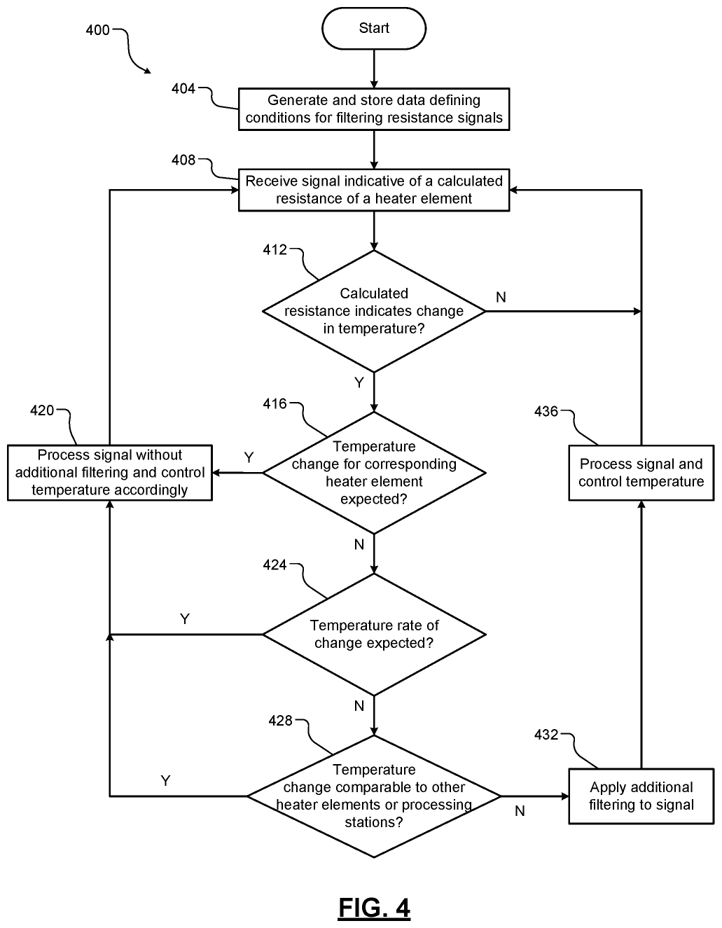

As described above, changes in the resistance values typically indicate a corresponding change in temperature. However, system variations unrelated to temperature changes may also cause changes in the calculated resistance values, such as variations caused by component wear, oxidation, loosening of fittings, connections, wiring, and splices, etc. These system variations may appear and increase in magnitude over the lifetime of the substrate support 200. Accordingly, the temperature calculation module 332 is configured to determine whether resistance changes are caused by an actual change in temperature or by a permanent or intermittent system variation. For example, only, the temperature calculation module 332 determines whether a change in resistance is expected in a given zone based on an expected change in temperature, an expected rate of change in temperature, and a comparison to changes in temperatures in other zones and/or processing stations. The filter module 334 applies filtering to the calculated resistance values based on the determination made by the temperature calculation module 332 as described below in FIG. 4 in more detail.

A temperature control module 344 receives a signal 346 indicating the calculated temperatures and controls the heater elements 228 accordingly. In other words, the signal 346 corresponds to one of (i) the temperatures as calculated using the unfiltered signals 324 and (ii) the temperatures as calculated using the signals 324 as filtered by the filter module 334 as described above. The temperature control module 344 is configured to output power control signals 348 to adjust power (e.g., current) provided to the heater elements 228 based on the calculated temperatures. In this manner, the controller 300 is configured to implement closed-loop control of the temperatures of the zones 224.

The temperature control module 344 may be further configured to receive the output signals 328 indicating the calculated power values and compare the calculated power values to commanded power indicated by the power control signals 348. In some examples, a difference between commanded and calculated power may be indicative of one or more faults, including, but not limited to, a wiring fault (e.g., disconnected or reversed wiring, a wiring short, etc.). The controller 300 may be configured to indicate the fault to a user (e.g., via a user interface/display 352 of the controller 300).

Similarly, the temperature calculation module 332 may be configured to determine and/or indicate a fault associated with a difference between the calculated temperatures and sensed temperatures (e.g., from the temperature sensor 340), a difference between respective calculated temperatures of the zones 224 (e.g., a difference greater than a threshold), a difference between the calculated temperatures and desired temperatures (e.g., as controlled via the signals 348), etc. For example, these differences may be further indicative of wiring or other faults, such as damaged components of the substrate support 200.

Referring now to FIG. 4, an example method 400 for selectively filtering signals corresponding to calculated resistances in a substrate support according to the present disclosure is shown. For example, the method 400 is implemented at least in part by the temperature calculation module 332. At 404, the method 400 generates and stores data (e.g., in memory of the controller 300) defining one or more conditions for filtering the signals 324 using the filter module 334. For example, the data may include a truth table identifying the one or more conditions for filtering the signals 324. In one example, the conditions correspond to determinations of whether a change in resistance is expected due to an expected change in temperature, whether a rate of change in the temperature is expected (i.e., within a defined range), and whether other zones and/or processing stations are experiencing a comparable change in temperature. The temperature calculation module 332 determines whether to filter the signals 324 in accordance with the truth table.

At 408, the method 400 (e.g., the temperature calculation module 332) receives one or more signals (e.g., the signals 324) indicative of a calculated resistance of a heater element in a given sampling period. While the temperature calculation module 332 receives signals corresponding to multiple heater elements per sampling period, the method 400 will be described with respect to a single heater element. At 412, the method 400 (e.g., the temperature calculation module 332) determines whether the calculated resistance indicates a change in temperature. For example, the temperature calculation module 332 compares the calculated resistance to a previously calculated resistance (e.g., as calculated in a previous sampling period). If true, the method 400 continues to 416. If false, the method 400 continues to 408.

At 416, the method 400 (e.g., the temperature calculation module 332) determines whether a temperature change for the corresponding heater element was expected. For F example, a temperature change may be expected during various operations related to substrate processing including, but not limited to, transfer of a substrate to and from the substrate support 200, initiation or discontinuation of various process steps (e.g., process or purge gas flow, pressure changes, plasma activation, changes in RF power, etc.), movement of components of the substrate support 200, etc. The method 400 determines whether the temperature change was expected based in part on the signals 340 indicating various operating parameters of the substrate processing system 100 as described above. If true, the method 400 continues to 420. If false, the method 400 continues to 424.

At 420, the method 400 (e.g., the temperature calculation module 332) processes the signal 324 without additional filtering from the filter module 334. For example, the method 400 calculates a temperature of the heater element, provides the signal 346 to the temperature control module 344, and controls the temperature of the heater element accordingly. An example method for controlling temperature is described in more detail in U.S. patent Ser. No. 10/633,742, issued on Apr. 28, 2020, the entire contents of which are incorporated herein by reference.

At 424, the method 400 (e.g., the temperature calculation module 332) determines whether a rate of change of the temperature indicated by the calculated resistance was expected. For example, the temperature calculation module 332 compares the temperature rate of change with one or more thresholds (e.g., thresholds defined in stored data). The thresholds may correspond to temperature rate of change limits associated with respective applications or processing steps. The temperature rate of change limits may be selected in accordance with maximum rates of change expected during a processing step being performed. If true, the method 400 continues to 420. If false, the method 400 continues to 428.

At 428, the method 400 (e.g., the temperature calculation module 332) determines whether the temperature change (e.g., a change in magnitude and/or rate of change) indicated by the calculated resistance is comparable to temperature changes calculated for other heater elements and/or processing stations. As noted above, the temperature calculation module 332 receives the signals 324 corresponding to a plurality of heater elements for different zones of the same substrate support 200 and may also receive the signals 324 corresponding to heater elements of additional substrate supports in different processing chambers or stations. Accordingly, the method 400 determines whether other heater elements or substrate supports are experiencing a similar change (e.g., a change in magnitude or a rate of change is within a range of, such as within 10%) as the temperature change corresponding to the calculated resistance. If true, the method 400 continues to 420. If false, the method 400 continues to 432.

At 432, the method 400 (e.g., the temperature calculation module 332) applies additional filtering to the signal 324. For example, the temperature calculation module 332 filters the signal 324 using the filter module 334. In other words, if the temperature change was not expected, the rate of the temperature change exceeds limits associated with a process step being performed, and heater elements in other zones and/or substrate supports are not experiencing a similar temperature change, the temperature calculation module 332 may determine that the change in the calculated resistance was not caused by an actual temperature change. Rather, the change in the calculated resistance may have been caused by a system variation such as oxidation, component wear, loosening of fittings, connections, and splices, etc. as described above. Accordingly, the filter module 334 filters the signal 324 to compensate for the system variation (e.g., by applying an offset) and the method 400 continues to 436.

At 436, the method 400 (e.g., the temperature calculation module 332) processes the signal 324 subsequent to the additional filtering applied by the filter module 334. For example, the method 400 calculates a temperature of the heater element using the filtered signal 324, provides the signal 346 to the temperature control module 344, and controls the temperature of the heater element accordingly.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above.” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A controller to control a temperature of a first substrate support in a substrate processing system, the controller comprising:
a resistance calculation module to calculate a first resistance of a first heater element of a plurality of heater elements of the first substrate support;
a temperature calculation module to calculate a first temperature of the first heater element based on the calculated first resistance; and
a filter module to filter a first signal that corresponds to the calculated first resistance,
wherein the temperature calculation module selectively causes the filter module to filter the first signal in response to a determination of whether at least one condition associated with operation of the substrate processing system is met.

2. The controller of claim 1, wherein the at least one condition corresponds to an operation of the substrate processing system that is associated with a temperature change in the first heater element.

3. The controller of claim 1, wherein the temperature calculation module determines, based on the calculated first resistance, whether a temperature change in the first heater element is expected and selectively causes the filter module to filter the first signal in response to a determination that the temperature change is not expected.

4. The controller of claim 1, wherein the temperature calculation module determines, based on the calculated first resistance, whether a rate of temperature change in the first heater element exceeds a threshold and selectively causes the filter module to filter the first signal in response to a determination that the rate of temperature change exceeds the threshold.

5. The controller of claim 1, wherein the temperature calculation module compares a first temperature change in the first heater element with a second temperature change in a second heater element and selectively causes the filter module to filter the first signal based on the comparison.

6. The controller of claim 5, wherein the second heater element is located in a second substrate support.

7. The controller of claim 1, wherein the filter module applies a resistance offset to the first signal in response to the determination of whether at least one condition associated with operation of the substrate processing system is met.

8. The controller of claim 1, further comprising a temperature control module configured to control power provided to the first heater element based on the first signal.

9. The controller of claim 1, wherein the resistance calculation module receives a first current corresponding to the first heater element, receives a first voltage corresponding to the first heater element, and calculates the first resistance based on the first voltage and the first current.

10. The controller of claim 9, wherein the temperature calculation module calculates the first temperature based on the calculated first resistance and a temperature coefficient of resistance of the first heater element.

11. A system, comprising:
a resistance calculation module to receive a current corresponding to a heater element in a substrate support, receive a voltage corresponding to the heater element, and calculate a resistance of the heater element based on the voltage and the current;
a temperature calculation module to calculate a temperature of the heater element based on the calculated resistance;
a filter module to filter a signal that corresponds to the calculated resistance,
wherein the temperature calculation module selectively causes the filter module to filter the signal in response to a determination of whether at least one condition associated with a change in the temperature of the heater element is met; and
a temperature control module configured to control power provided to the heater element based on the signal as filtered by the filter module.

12. The system of claim 11, wherein the temperature calculation module determines, based on the calculated first resistance, whether at least one of (i) the change in the temperature of the heater element is expected and (ii) a rate of the change in the temperature of the heater element exceeds a threshold.

13. The system of claim 11, wherein the temperature calculation module selectively causes the filter module to filter the signal in response to a determination that the change in the temperature of the heater element is not expected, a rate of the change in the temperature of the heater element exceeds a threshold, and the change in the temperature of the heater element is not within a range of a change in a temperature of another heater element.

14. A method of controlling a temperature of a first substrate support in a substrate processing system, the method comprising:
calculating a first resistance of a first heater element of a plurality of heater elements of the first substrate support;
calculating a first temperature of the first heater element based on the calculated first resistance; and
selectively filtering a first signal that corresponds to the calculated first resistance in response to a determination of whether at least one condition associated with operation of the substrate processing system is met.

15. The method of claim 14, wherein the at least one condition corresponds to an operation of the substrate processing system that is associated with a temperature change in the first heater element.

16. The method of claim 14, further comprising determining, based on the calculated first resistance, whether a temperature change in the first heater element is expected and selectively filtering the first signal in response to a determination that the temperature change is not expected.

17. The method of claim 14, further comprising determining, based on the calculated first resistance, whether a rate of temperature change in the first heater element exceeds a threshold and selectively filtering the first signal in response to a determination that the rate of temperature change exceeds the threshold.

18. The method of claim 14, further comprising comparing a first temperature change in the first heater element with a second temperature change in a second heater element and selectively filtering the first signal based on the comparison.

19. The method of claim 18, wherein the second heater element is located in a second substrate support.

20. The method of claim 14, further comprising controlling power provided to the first heater element based on the first signal.
